(19) United States
(12) Patent Application Publication
(10) Pub. No.: US 2013/0319848 A1
(43) Pub. Date: Dec. 5, 2013

(54) SPUTTERING PROCESS

(71) Applicant: VON ARDENNE ANLAGENTECHNIK GMBH, Dresden (DE)

(72) Inventors: Joerg NEIDHARDT, Dresden (DE); Gintautas ABRASONIS, Dresden (DE)

(21) Appl. No.: 13/905,722

(22) Filed: May 30, 2013

(30) Foreign Application Priority Data
Jun. 1, 2012 (DE) 10 2012 209 293.5

(51) Int. Cl. C23C 14/35

(52) U.S. Cl. CPC C23C 14/352
USPC 204/192.12

(57) ABSTRACT

In a process for coating a substrate, the substrate is arranged opposite a removal surface of a target and the coating material is atomized by sputtering under an inert or reactive-gas-containing process gas and deposited on the substrate. The coating takes place from a mixed target with at least one target component A and a target component B. At the beginning of the sputtering process, the distribution of the target components A and B in a superficial target layer of the removal surface is modified by high-power impulse magnetron sputtering.

### CROSS REFERENCE TO RELATED APPLICATIONS

This application claims priority of German application No. DE 10 2012 209 293.5 filed on Jun. 1, 2012, the entire contents of which is hereby encorporated by reference herein.

### BACKGROUND ART

The invention relates generally to a sputtering process for depositing a layer on a substrate.

In sputtering, a substrate to be coated is arranged opposite a removal surface of a target under a vacuum in an inert or reactive-gas-containing process gas and the coating material is atomized by means of magnetron sputtering and deposited on the substrate. For this purpose, a plasma is ignited between the substrate to be coated and a cathode and the positive charge carriers thereof remove the upper layers of a target surface by what is known as the sputtering effect (sputtering, i.e. ejection of atoms from the solid surface induced by ion bombardment). A wide range of materials can be sputtered, without or with the presence of reactive gas, and in the latter case deposited for example as an oxide or nitride on a substrate lying opposite the removal surface of the target. In a comparable way, it is also possible to use and sputter material mixtures and compounds as a target material.

Important quality characteristics of the sputtering processes are on the one hand the properties of the deposited layers and on the other hand the efficiency of the process, which is linked in particular with the sputtering rate that can be achieved and controlled.

In recent years, a process known as High-Power Impulse Magnetron Sputtering (HiPIMS) has been used for various applications. HiPIMS is a sputtering process with pulsed energy input, in which the power density introduced at the target can reach approximately 30 times to over 100 times the values that are customary in conventional DC magnetron sputtering. Such a process is known from DE 10 2008 028 141 A1 for the depositing of an indium tin oxide layer. By means of a very high power current density in the pulse, which is greater than a DC discharge by a factor of 100-500, and pulse durations of less than 40 μs, an indium tin oxide layer with particularly advantageous mechanical, chemical and optical properties has been produced.

On account of the high power density, the process is characterized by a high degree of ionization and increased energy of the layer-forming particles, to which the particular properties of the deposited layers are attributable. For instance, layers deposited by means of HiPIMS have a very dense structure without any major structural irregularities. Consequently, these layers are also distinguished by a high degree of hardness, good corrosion resistance and a low sliding wear coefficient, which make them suitable for example for the surface finishes of tools.

However, the sputtering rate of the process is much lower in comparison with conventional DC (direct voltage) sputtering and MF (mid-frequency) sputtering, and so it is not effective enough at present for industrial and large-area applications. The low rate is attributable to the high proportion of ionized target particles that are accelerated back to the cathode, and are consequently no longer available for layer formation. Attempts to increase the rate by means of adapting the magnetic field or setting the operating point in reactive processes only produce the desired success to a limited extent.

Many materials can be deposited on substrates by means of conventional DC and MF sputtering with an element-specific sputtering and depositing rate, while the processes can also be controlled well for large cathodes, different substrate materials and continuous-flow industrial installations. The sputtering rate, which indicates the number of target atoms sputtered, is a function of numerous properties of the plasma ions and the target material. It is particularly dependent on the ion mass, the energy thereof and the angle of incidence thereof as well as the mass of the target atoms, the packing density thereof and the binding energy thereof. It is generally conducive to the sputter yield if a considerable amount of energy of the ion is absorbed in the uppermost monolayers of the target as a result of a high specific stopping power or a favorable geometry. This energy is then also available in the form of collision cascades for overcoming the surface binding energy. The sputter yield of target materials that are lighter in comparison with the sputtering gas tends to be low, because the energy transfer is unfavorable for the ions of the target materials and the ion penetrates deeply, and less of its original energy is available at the surface for detaching target atoms.

If, however, heavier atoms are added to the light target element, these increase the stopping power and more energy is available in the region near the surface for “sputtering”. This effect is known as increasing the sputtering rate or Sputter Yield Amplification (SYA) (S. Berg et al. Preferential sputtering effects in thin film processing” J. Vac. Sci. Technol. A 17(4), July/August 1999) and can be used for increasing the rate of sputtering processes. The aim is consequently to incorporate a defined number of heavy elements, for example tungsten, in an atomically dispersed manner in a light target that is difficult to sputter, for example carbon. One way in which this can be achieved is by deliberate alloy formation in the target, for example tungsten carbide (WC), or else also by enrichment of the target surface, carried out in situ, with a further component by means of serial co-sputtering (WO 2005/59197 A2).

However, the technical complexity of the in-situ solution is very high, since a separate gas separation and separate cathode arrangements with the associated cathode surroundings are required for the serial sputtering processes. Moreover, globally uniform distribution of the admixtures at the atomic level only applies to alloys, which greatly restricts the ratio between the atoms to be sputtered and the admixture. For differing compositions, however, the requirements for the fineness of the grain size distribution in the mixed target are very stringent, and it is almost impossible to set the atomically fine distribution that is necessary, which greatly limits the efficiency of the usually expensive dopants.

The invention is based on the object of providing a sputtering process with which the sputtering rates can be increased with less technical complexity, as known from the prior art, and without any loss in the ability to set the properties of the layer.

### BRIEF SUMMARY OF THE INVENTION

A description is given of a sputtering process that uses a mixed target with at least one target component A and a target component B both for the depositing of a single-component layer and for the depositing of a multi-component layer on a substrate, wherein the distribution of the target components at the surface is influenced in situ at the beginning and in the further course of the sputtering process by means of high-power impulse magnetron sputtering.

In the following, a distinction is to be made between a target component and a layer component. A target component is usually also contained in the layer, and consequently is a layer component in an unchanged form or, for example in the case of reactive coating, in a changed form. Similarly, however, a target component may only be technologically required, so that it is not desired as a layer component, or only in such a proportion that the nature of the layer is not influenced. In the case of such constituents of a layer, reference is also made to impurities.

Accordingly, layer compositions on the substrate in which one layer component, atoms or compounds such as for example oxides, nitrides or others, makes up the essential proportion, and in particular the proportion that is essential for the function of the layer, and one or more layer components are only contained to an order of magnitude that comprises impurities should be referred to as a single-component layer. These impurities are technologically determined, for example by the commercially customary purity of the materials used, the production of the target or for the stabilization of a reactive process. Such impurities usually have proportions by weight of a few percent.

As a result of the superficial modification of the distribution of the target components, this process step is subsequently also referred to simply as component distribution, the sputtering rate can be increased for the subsequent sputtering process and the atomic fineness of the dispersion of the target component A in the removal surface that is required for this can be set.

The fact that the HiPIMS process is used for this means that the high degree of ionization of the atomized target atoms, and the associated high probability that they will return to the target, can be used. The target components are in this case initially sputtered and, on account of the high energy density of the process, ionized in a very high proportion. On account of this, they are accelerated back to the target and deposited there in a homogeneously intermixed manner as a superficial layer. The distribution of the target components can also be influenced by way of the degree of ionization of the target materials.

Coming into consideration as target components are those that are required for the layer or, as described above, are merely technologically required for single-component layers, or meet both requirements. Such admixtures, also referred to here for distinguishing purposes as target component B, that have a rate-increasing effect may be used in particular.

The combination of the process step of superficial component distribution with the actual depositing process does not require any, or only little, additional installation technology. Moreover, it can be used both for reactive and non- reactive depositions of a wide variety of target materials (target component A). Good results have been achieved for example with carbon, aluminum, titanium, titanium oxide, zinc oxide, the latter also doped, or ITO. On account of the possibility of homogenization of the technologically required admixture, other coating materials that are more difficult to control may also be deposited with the process according to the invention and with an increased sputtering rate.

Moreover, the costs for target production can be reduced, since there are no requirements with regard to morphology for the original target. The morphology desired for the deposition is produced by the initial restructuring and distribution processes.

It proves to be of advantage, in addition, that the initial HiPIMS for the surface structuring and distribution can continue to be used with the common sputtering processes without any technical equipment modifications. The fact that, according to one refinement of the process, the actual coating is continued by means of DC or MF sputtering means that the advantages thereof can be included. Apart from the advantages described above, this is particularly the higher sputtering rate in comparison with HiPIMS.

On account of the same installation configuration for both processes, in a further refinement of the process it is additionally possible for the superficial component distribution to be repeated multiply, preferably periodically, in the course of the coating process, so that the optimum distribution is always available at the removal surface. The point in time of the renewed component distribution can be empirically determined by way of the layer thickness of the homogenized surface layer that can be achieved by means of the HiPIMS component distribution and the sputtering rate that can be achieved as a result. A thus determined alternation between HiPIMS mode and DC/MF mode can be retained for the coating process.

Use of the HiPIMS process for the homogenization and equally for the deposition makes the return acceleration of ionized admixture atoms more probable and, because of that, the concentration of such atoms as an impurity in the deposited layer is much less than has been found for the conventional processes. This effect widens the possibilities of the admixtures that can be used for technological aspects, in particular for the selection of such target components with which a highest possible sputtering rate increase or sputter yield amplification (SYA) can be achieved, and therefore a major disadvantage of HiPIMS can be reduced by combining it with the process of increasing the sputtering rate. Use of the HiPIMS process for the actual layer deposition may then be of advantage, for example, if an acceptable sputtering rate is already achievable by the coating material itself, or for example by suitable admixtures, and/or if the particular layer properties linked with the process are desired.

For the technologically required admixtures described above, it is possible to add very small amounts of these target components to the target for each of the coating processes that are used and described here, on account of the added step of component distribution. This has the consequence that the proportion of the admixture can be kept at low percentages by weight also in the deposited layer, or the admixtures are not precipitated in the layer.

As described above, rate-increasing target components come into consideration in particular as admixtures for the target material. Such admixtures may, according to one refinement of the process, have an atomic or molecular mass that differs distinctly from the target component A, which represents the actual layer material, so that various effects associated therewith of impulse transfer can be used. Tungsten, bismuth, tantalum, molybdenum or others come into consideration for example as target component B, since they are heavy and inexpensive in comparison with the customary layer components that are industrially used and, moreover, do not have any, or only little, influences on the layer properties. If the atomic or molecular mass of the target component A is less than that of the target component B, an increase in the sputtering rate takes place as a result of the concentration of the energy input into the restructured zone near the surface, since the heavy admixtures effectively increase the stopping power in this zone. Possible material combinations of target components are, for example, carbon with tungsten admixtures or titanium with bismuth admixtures.

The rate-increasing effects may also be achieved by such admixtures which, according to a further refinement, increase the sublimation of the target component A, i.e. lower the energy thereof that is required for leaving the target. Suitable as admixtures with such an effect are, for example, oxygen as a reactive gas or as an oxide component of a target, which as a result of a more efficient formation of a homogeneous surface oxide on the target increase the sputter yield on account of the sublimation contribution as a result of the higher vapor pressure of this oxide. The higher-energy bombardment during the HiPIMS thereby increases the diffusion and results in a thicker oxide that is more compatible for this case than can be achieved for pure sputtering. An example of this is the sputtering of silicon in an oxygen-containing atmosphere for the depositing of stoichiometric or substoichiometric silicon oxide.

### BRIEF DESCRIPTION OF THE DRAWING FIGURES

The invention is to be explained in more detail below on the basis of an exemplary embodiment, in which a target which comprises along with target component A also target component B is used as a mixed target for depositing a layer of the target component A on a substrate. In the associated drawing,

FIG. 1A and FIG. 1B show a region of the removal surface of the target before and after the process for component distribution.

### DETAILED DESCRIPTION

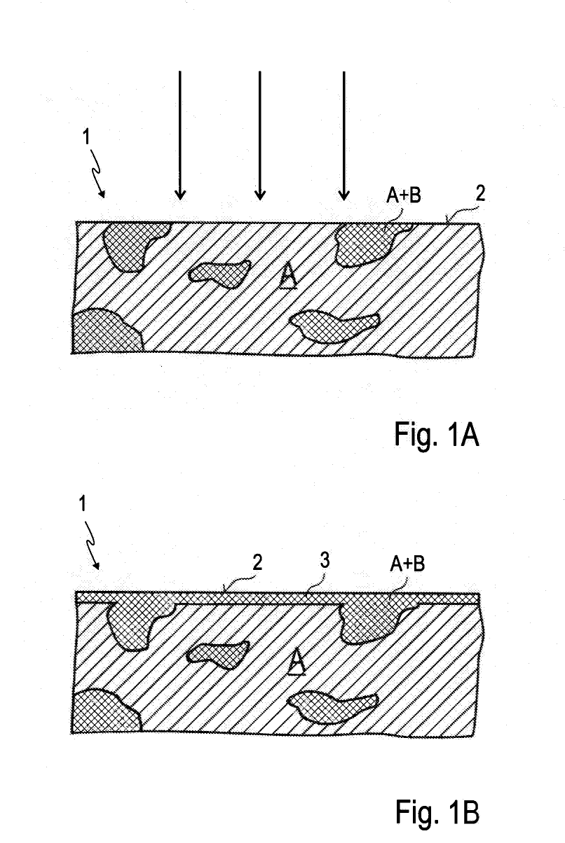

In FIG. 1A, the distribution of the target component A, for example carbon, as the layer-forming target component, and of the target component B in a region near the surface to be atomized of the mixed target 1 is represented. Target component A forms the essential part of the target material. Distributed in the matrix of the target component A are regions in which there is a mixture of the target components A and B. In the exemplary embodiment, these regions are of tungsten carbide, since tungsten was admixed as target component B in the form of tungsten carbide during target production with a specific grain size distribution with a lower limit, or else was redistributed or segregated in the thermally activated sintering processes.

In this connection, the surface of the mixed target 1 is exposed to an HiPIMS process (represented by arrows directed toward the surface), wherein the proportions of the HiPIMS pulse sequence in alternation with DC or MF sputter sequences have been empirically determined on the basis of the optimization of the rate increase. As a result of this, a high-energy plasma is generated over the target surface, also comprising ionized vapor of the target components A and B. These are for the most part accelerated back onto the target surface and form on it a superficial target layer 3, in which both target components are uniformly mixed (FIG. 1B).

The commonly used devices for magnetron sputtering with a planar or tubular magnetron, with the process gas feeding and distribution that is required for an inertly or reactively conducted process as well as a power supply suitable for the power densities and pulse durations, may be used for carrying out the process according to the invention in the various refinements described above.

1. Process for coating a substrate, comprising: arranging a substrate to be coated opposite a removal surface of a target, atomizing coating material of the removal surface by sputtering under an inert or reactive-gas-containing process gas and depositing the coating material on the substrate, employing as a coating material source a mixed target with at least one target component A and a target component B and, at a beginning of the sputtering, modifying distribution of the target components A and B in a superficial target layer of the removal surface by high-power impulse magnetron sputtering.

2. Process for coating a substrate according to claim 1, wherein after modification of the distribution of the target components in the target layer of the mixed target, the coating process is continued by DC or MF sputtering.

3. Process for coating a substrate according to claim 2, further comprising: modifying the distribution of the target components in the target layer of the mixed target at least one more time in the course of the coating process.

4. Process for coating a substrate according to claim 1, wherein after modification of the distribution of the target components in the target layer of the mixed target, the coating process is continued by high-power impulse magnetron sputtering.

5. Process for coating a substrate according to claim 1, wherein target component A comprises a material of the layer to be deposited and target component B is an admixture for increasing sputtering rate of the coating process that is either not integrated in the layer to be deposited, or only in small proportions of a few percent by weight.

6. Process for coating a substrate according to claim 5, wherein atomic or molecular mass of target component A is less than that of target component B.

7. Process for coating a substrate according to claim 5, wherein target component B comprises a material that increases sublimation of target component A.
